(19) United States
(12) Patent Application Publication
(10) Pub. No.: US 2009/0323156 A1
(43) Pub. Date: Dec. 31, 2009

(54) Method of forming electrochromic layer pattern, method of manufacturing electrochromic device using the same, and electrochromic device including electrochromic layer pattern

(76) Inventors: Hyun-Woo Shin, Gyeonggi-do (KR); Ki-Seok Jang, Daegu (KR); Jin-Young Park, Jeollanam-do (KR); Min-Ho Choi, Daejeon (KR); Tae-Su Kim, Daejeon (KR); Su-Hee Lee, Seoul (KR); Jae-Hong Kim, Seoul (KR); Boo-Kyung Kim, Daejeon (KR)

Correspondence Address: MCKENNA LONG & ALDRIDGE LLP, 1900 K STREET, NW, WASHINGTON, DC, 20006, US

(21) Appl. No.: 12/310,734

(22) PCT Filed: Sep. 4, 2007
(86) PCT No.: PCT/KR2007/004256

§ 371 Date: Mar. 5, 2009

(30) Foreign Application Priority Data
Sep. 6, 2006 (KR) 10-2006-0085616

(51) Int. Cl. G02F 1/15; G03F 7/20

(52) U.S. Cl. 359/265; 430/321

(57) ABSTRACT

A method for forming an electrochromic layer pattern includes forming a transparent electrode layer and a photoresist layer on a transparent substrate, forming a photoresist pattern by laser interference lithography, and depositing an electrochromic layer pattern on the transparent electrode through openings defined by the photoresist pattern by depositing an electrochromic layer on a front surface of the substrate and then lifting up the photoresist pattern. An insulation layer may be further formed between the transparent layer and the photoresist layer. Here, the electrochromic layer may be formed after an insulation layer pattern is formed using the photoresist pattern as an etching mask. In this case, the electrochromic layer pattern is formed in openings defined by the insulation layer pattern. As a result, a contact surface area between the electrochromic layer pattern and the ion conductive layer is increased to ensure a rapid response speed.

### TECHNICAL FIELD

The present invention relates to a method for manufacturing an electrochromic device, and more particularly to a method forming an electrochromic layer pattern of an electrochromic device, a method for manufacturing an electrochromic device using the above method, and an electrochromic device having the electrochromic layer pattern.

### BACKGROUND ART

An electrochromic device (ECD) is a color emitting display device using electrochromic material that is colored or decolored by means of electrochemical oxidation or reduction according to an applying direction of electric current. The ECD is classified into a cathodic ECD and an anodic ECD. The cathodic ECD keeps a transparent color if current is not applied thereto, but the cathodic ECD exhibits an inherent color according to the kind of electrochromic material if current is applied thereto. In addition, if the current direction is reversed, the color of the electrochromic material is decolored and thus restored into the transparent color. The anodic ECD is operated opposite to the cathodic ECD. The ECD with such properties is widely used for mirrors and sunroofs of vehicle, smart windows, outside displays and so on.

The electrochromic material includes transition metal oxides, Prussian blue, phthalocyanines, viologens, conducting polymers, fullerenes, and so on.

The transition metal oxide includes cathodic electrochromic materials such as WO₃, MoO₃, Nb₂O₅ and TiO₂, and anodic electrochromic materials such as NiO, Ir₂O₃, Rh₂O₃, CO₃O₄, Fe₂O₃, Cr₂O₃ and V₂O₅. Transition metal oxides, Prussian blue and phthalocyanines are inorganic electrochromic materials with excellent UV (ultraviolet) stability.

The conducting polymers include polyaniline, polypyrrole, polythiophene, polycarbazole, and so on. Viologens and conducting polymers are organic electrochromic materials with excellent processibility and allowing various colors.

The above electrochromic materials may be used to make various ECD with various combinations such as inorganic ECD, organic ECD and inorganic-organic hybrid ECD.

FIG. 1 schematically shows a basic configuration of an ECD. Referring to FIG. 1, the ECD 10 includes a first glass substrate 20 on which an upper electrode 30 made of transparent material and having an electrochromic layer 40 is laminated, a second glass substrate 80 on which a lower electrode 70 made of transparent material and having an ion storage layer 60 is laminated such that the second glass substrate 80 faces the first glass substrate 20, and an ion conductive layer 50 injected between the electrochromic layer 40 and the ion storage layer 60.

The first and second glass substrates 20, 80 are composed of resin films made of glass or transparent material. The upper and lower electrodes 30, 70 are configured with transparent electrodes made of ITO or FTO. The ion storage layer 60 may be substituted with electrochromic material with a polarity opposite to the electrochromic layer 40, and it may be excluded on occasions. The ion conductive layer 50 is made of liquid electrolyte, gel electrolyte, solid electrolyte, polymer electrolyte, ionic liquid, and so on.

The ECD 10 configured as mentioned above is colored when a voltage is applied between the upper electrode 30 and the lower electrode 70 to flow current from the ion storage layer 60 to the electrochromic layer 40. Also, the ECD 10 is decolored when a voltage opposite to the coloring case is applied thereto to flow current from the electrochromic layer 40 to the ion storage layer 60. Meanwhile, the ECD may also be colored or decolored at a current flow opposite to the above depending on whether the electrochromic layer 40 is cathodic or anodic.

Meanwhile, for coloring the ECD 10, ions or electrons should be diffused to the electrochromic layer 40 through the ion conductive layer 50 to cause oxidation or reduction of the electrochromic material. However, in case the electrochromic layer 40 is made of an inorganic film, ions or electrons participating in the coloring reaction are slowly diffused, so the ECD shows a slow response speed. In addition, since the inorganic film has a weak mechanical strength, the electrochromic layer may be broken in case the ECD is made using a flexible substrate, so the inorganic film may deteriorate durability of the ECD.

Conventionally, to solve this problem, the electrochromic layer 40 was made using a porous film, or nano-sized holes were patterned in the electrochromic layer 40 to increase a surface area for electrochromic reaction.

However, in case the electrochromic layer 40 is made using a porous film, it is required to disperse nano-sized electrochromic particles into an organic solvent, coating it onto a substrate in a paste form, and then drying and sintering the solvent, which results in deteriorated productivity. In addition, the electrochromic layer 40 should have a great thickness to obtain a desired coloring condition, so there is a limit in making the ECD thinner.

In addition, the method of patterning nano-sized holes in the electrochromic layer 40 shows bad productivity since the hole patterning needs a separate mask and also requires a plurality of additional processes such as a mask aligning process, a photoresist process, an etching process and a washing process.

### DISCLOSURE

### Technical Problem

The present invention is designed in consideration of the above problems, and therefore it is an object of the invention to provide a method for patterning an electrochromic layer, which may improve a coloring or decoloring speed by increasing a contact area between an ion conductive layer and an electrochromic layer included in an ECD using a laser interference lithography without needing a masking process, also may prevent breakdown of an electrochromic layer though the ECD is configured so that an electrochromic layer made of an inorganic film is deposited on a flexible plastic substrate; a method for manufacturing an ECD using the patterning method; and an ECD manufactured by the method.

### Technical Solution

In order to accomplish the above object, in one aspect of the present invention, there is provided a method for forming an electrochromic layer pattern, which includes forming a sheet-type transparent electrode layer on a transparent substrate; forming a photoresist layer on the transparent electrode layer; patterning the photoresist layer by means of laser interference lithography to form a photoresist pattern having openings that expose the transparent electrode layer at regular intervals; and forming an electrochromic layer pattern in the openings by depositing an electrochromic layer on a front surface of the transparent substrate and lifting up the photoresist pattern.

In another aspect of the present invention, there is also provided a method for manufacturing an ECD, which includes forming a sheet-type transparent electrode layer on a transparent substrate; forming an insulation layer on the transparent electrode layer; forming a photoresist layer on the insulation layer; patterning the photoresist layer by means of laser interference lithography to form a photoresist pattern having openings that expose the insulation layer at regular intervals; etching the insulation layer using the photoresist pattern as an etching mask to form an insulation layer pattern having openings that expose the transparent electrode layer at regular intervals; and forming an electrochromic layer pattern in the openings defined by the insulation layer pattern by depositing an electrochromic layer on a front surface of the transparent substrate and lifting up the photoresist pattern.

In the present invention, the electrochromic layer pattern may have different shapes depending on the type of photoresist used in the laser interference lithography and the time of laser beam exposures. As an example, the electrochromic layer pattern has a lattice structure in which strip-type patterns are arranged in two dimensions. As another example, the electrochromic layer pattern has a lattice structure in which square-type patterns are arranged in two dimensions. As still another example, the electrochromic layer pattern has a strip structure in which strip-type patterns are arranged in one dimension.

In order to accomplish the above object, the present invention also provides a method for manufacturing an ECD, which uses the substrate module prepared by the above electrochromic layer pattern forming method.

In one aspect of the present invention, a substrate in which a transparent substrate, a transparent electrode layer and an electrochromic layer pattern are laminated is used as a lower substrate module, and a substrate in which a transparent substrate and a transparent electrode layer are laminated is used as an upper substrate module. And then, the upper and lower substrate modules are fixed in a spaced-apart relationship using a spacer, and both substrate modules are sealed except for an injection hole used for injection of an ion conductive layer. And then, an ion conductive layer is injected through the injection hole, and then the upper and lower substrate modules are sealed to completely manufacture an ECD.

In another aspect of the present invention, a substrate module in which a transparent substrate, a transparent electrode layer, an insulation layer pattern and an electrochromic layer pattern are laminated is used as a lower substrate module, and a substrate module in which a transparent substrate and a transparent electrode layer are laminated is used as an upper substrate module. Here, the electrochromic layer pattern is formed in openings defined by the insulation layer pattern. And then, an upper surface of the insulation pattern is closely adhered and fixed to a surface of the transparent electrode layer of the upper substrate module, and both substrate modules are sealed except for an injection hole used for injection of an ion injection layer. And then, an ion conductive layer is injected through the injection hole, and then the upper and lower substrate modules are sealed to completely manufacture an ECD.

In the ECD manufacturing method according to the present invention, explained above, the upper substrate module may be configured identical to the lower substrate module. In this case, the electrochromic layer patterns provided to both substrate modules have polarities different from each other. For example, in case an electrochromic layer pattern of any one substrate module is composed of cathodic electrochromic material, an electrochromic layer pattern of the other substrate module is composed of anodic electrochromic material. In addition, in case the insulation layer pattern is provided to both substrate modules, when both substrate modules are coupled, both substrate modules are fixed with upper surfaces of their insulation layer patterns facing each other and then sealed after an ion conductive layer is injected therein.

In order to accomplish the above object, in one aspect of the present invention, there is provided an electrochromic device (ECD), which includes first and second transparent substrates arranged to face each other; first and second sheet-type transparent electrodes respectively formed on the first and second transparent substrates to face each other; an electrochromic layer pattern formed on at least one of the first and second transparent electrodes through openings of a photoresist pattern formed by laser interference lithography; and an ion conductive layer for sealingly filling a space defined by the electrochromic layer pattern and surfaces of the first and second transparent electrodes.

In another aspect of the present invention, there is also provided an ECD, which includes first and second transparent substrates arranged to face each other; first and second sheet-type transparent electrodes respectively formed on the first and second transparent substrates to face each other; an insulation layer pattern formed on at least one of the first and second transparent electrodes and having openings regularly repeated; an electrochromic layer pattern formed in the openings of the insulation layer pattern; and an ion conductive layer for sealingly filling a space defined by a surface of the insulation layer pattern, a surface of the electrochromic layer pattern, and surfaces of the first and second transparent electrodes.

### DESCRIPTION OF DRAWINGS

These and other features, aspects, and advantages of preferred embodiments of the present invention will be more fully described in the following detailed description, taken accompanying drawings. In the drawings:

FIG. 1 is a schematic view showing a general configuration of an ECD;

FIG. 2 is a schematic diagram showing an Ar (351 nm) laser interference lithography device used in a method for forming an electrochromic layer pattern according to a preferred embodiment of the present invention;

FIG. 3 shows a measurement result of a photoresist pattern exposed and developed through a laser interference lithography process;

FIGS. 4 to 7 are schematic diagrams subsequently illustrating processes of a method for forming an electrochromic layer pattern according to a first embodiment of the present invention;

FIGS. 8 to 10 are partially expanded perspective views showing a photoresist pattern formed through the laser interference lithography;

FIGS. 11 to 13 are partially expanded perspective views showing an electrochromic layer pattern formed using the photoresist patterns of FIGS. 8 to 10;

FIGS. 14 and 15 are schematic diagrams subsequently illustrating processes of a method for manufacturing an according to the first embodiment of the present invention;

FIGS. 16 to 18 are schematic diagrams subsequently illustrating processes of a method for forming an electrochromic layer pattern according to a second embodiment of the present invention; and

FIGS. 19 and 20 are schematic diagrams subsequently illustrating processes of a method for manufacturing an according to the second embodiment of the present invention.

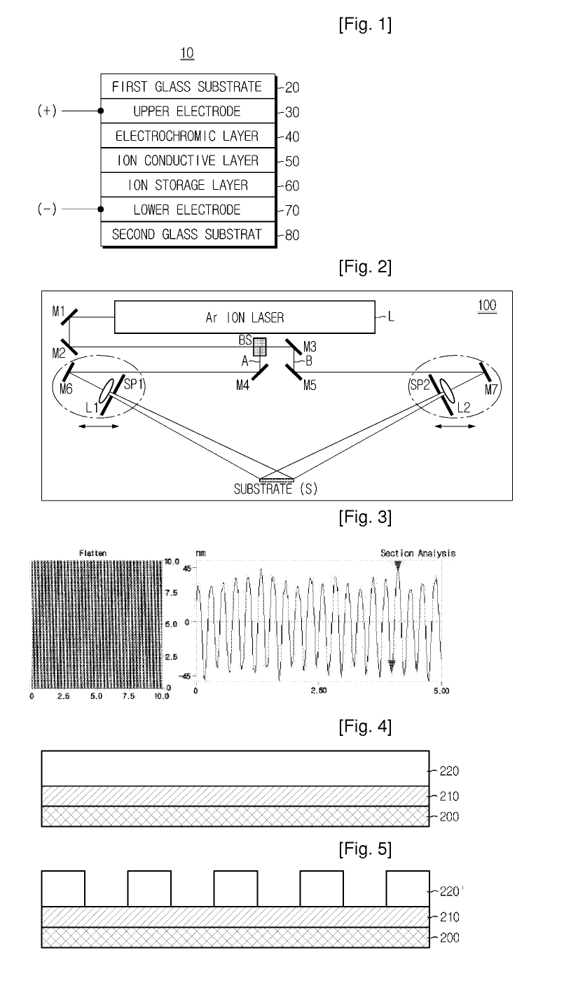

### REFERENCE NUMERALS OF ESSENTIAL PARTS IN THE DRAWINGS

100: laser interference lithography device
200, 400: transparent substrate
210, 410: transparent electrode layer
220′, 430′: photoresist pattern
230′, 440′: electrochromic layer pattern
420′: insulation layer pattern
300, 450: upper substrate module
310, 460: lower substrate module
320, 470: ion conductive layer

### BEST MODE

Hereinafter, preferred embodiments of the present invention will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present invention on the basis of the principle that the inventor is allowed to define terms appropriately for the best explanation. Therefore, the description proposed herein is just a preferable example for the purpose of illustrations only, not intended to limit the scope of the invention, so it should be understood that other equivalents and modifications could be made thereto without departing from the spirit and scope of the invention.

A method for forming an electrochromic layer pattern according to the present invention uses laser interference lithography. The laser interference lithography allows forming a photoresist pattern without using a mask. That is to say, with no mask, two laser beams are irradiated to a photoresist layer from different positions. Then, the photoresist layer becomes photosensitive at a portion where laser waves are overlapped, due to the interference that is a feature of laser source. And then, if the photoresist layer is developed, a photoresist pattern in which strip-type openings are regularly repeated is formed.

FIG. 2 schematically shows an Ar (351 nm) laser interference lithography device 100 used in a method for forming an electrochromic layer pattern according to a preferred embodiment of the present invention.

Referring to FIG. 2, laser beam emitted from a laser generator L changes its path with passing through mirror plane optical systems M1, M2, and then incident onto a beam splitter BS. The laser beam incident on the beam splitter BS is separated into a first laser beam A and a second laser beam B for forming an interference pattern. The first laser beam A expands its beam width while passing through a first object lens L1 via mirror plane optical systems M4, M6, and its noise is removed while the first laser beam A passes through a first pin hole SP1 positioned at a focus surface of the first object lens L1. Similarly, the second laser beam B also expands its beam width and its noise is removed while the second laser beam B passes through mirror plane optical systems M3, M5, M7, a second object lens L2, and a second pin hole SP2. The noise-free first and second laser beams A, B are irradiated together at a predetermined angle to a surface of a substrate S on which a photoresist layer is formed. Energy distribution of the first and second laser beams A, B already passing through the first and second pin holes SP1, SP2 is substantially similar to Gaussian distribution, so two laser beams A, B irradiated to the substrate S form regular interference patterns. Thus, the photoresist layer on the substrate S becomes photosensitive along the regular intervals. In addition, if the photosensitive photoresist is developed, a photoresist pattern in which strip-type openings are formed regularly is obtained.

FIG. 3 shows a measurement result of a photoresist pattern, exposed and developed by means of laser interference lithography, measured using AFM (Atomic Force Microscopy). A left portion in FIG. 3 is a photograph obtained by photographing the photoresist pattern from above, in which a black strip indicates a strip-type opening and a white strip indicates a photoresist layer positioned among openings. Also, a right portion in FIG. 3 is a graph quantitatively showing an AFM measurement result. Seeing FIG. 3, it would be understood that fine patterns with uniform depth and pitch may be formed when a photoresist is patterned using laser interference lithography.

The laser interference lithography explained above may theoretically form a regular pattern with high resolution since it allows patterning up to ½ of a laser wavelength. However, if the wavelength of laser is decreased to enhance resolution of the pattern, the beam reflected from a target causes multi interference effect, which may deteriorate resolution of the pattern. Thus, for forming a high resolution pattern, it is desirable to fix the phase of laser beam and make a coating on the target for preventing reflection of the beam such that the multi interference effect is reduced.

Meanwhile, during the laser interference lithography, laser beam may be irradiated once again with rotating a target as much as 90 degrees after first irradiation of laser beam. In this case, a photoresist pattern in a lattice structure repeated in two dimensions may be obtained. If the photoresist is positive, a lattice structure is formed due to two-dimensional arrangement (X direction and Y direction) of strip-type openings, while, if the photoresist is negative, a lattice structure is formed due to two-dimensional arrangement (X direction and Y direction) of square-type openings.

FIGS. 4 to 7 are schematic diagrams subsequently illustrating processes of a method for forming an electrochromic layer pattern according to a first embodiment of the present invention.

First, as shown in FIG. 4, a transparent electrode layer 210 is formed on a transparent substrate 200. Then, a photoresist layer 220 is formed on the transparent electrode layer 210 by means of spin coating. The substrate 200 may be made of glass or various transparent films, and the transparent electrode layer 210 may be made of materials such as ITO and FTO. The transparent film may also be made of flexible plastic material. The critical photosensitivity of the photoresist layer 220 is an essential factor for obtaining a desired unevenness or aspect ratio. Thus, the photoresist material preferably adopts a I-line (365 mm) photoresist, though various kinds of photoresist are also available. Also, the thickness of the photoresist layer 220 is controlled in the range of 200 to 1000 nm.

Subsequently, as shown in FIG. 5, a photoresist pattern 220′ is formed by means of laser interference lithography. That is to say, the photoresist layer 220 is firstly exposed to light using the laser interference lithography device shown in FIG. 2, and then the photoresist layer 220 is secondly exposed to light with the substrate being rotated as much as 90 degrees. After that, the photoresist layer 220 is developed. During the exposure process, Ar ion layer of 351 nm is preferably used, but the present invention is not limited thereto. If the photoresist layer 220 is exposed to light, a photoresist pattern 220′ having a lattice structure is obtained.

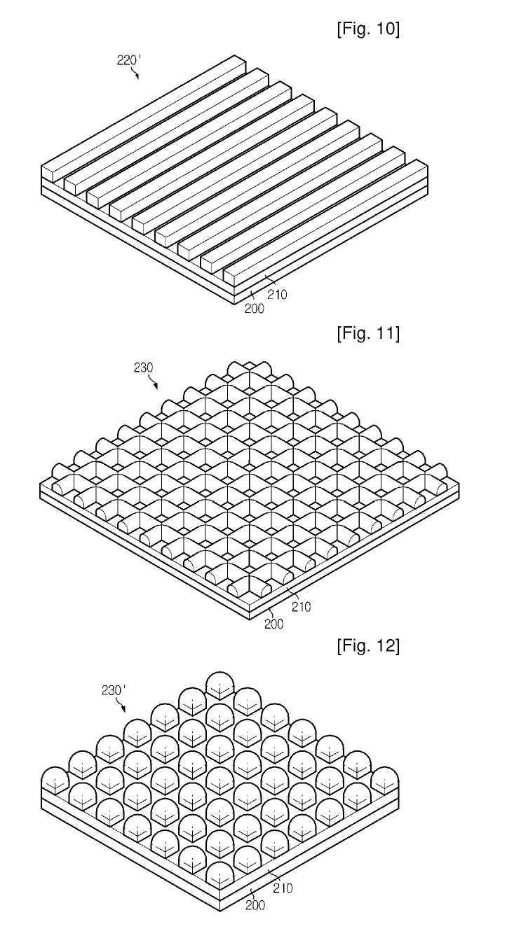

Here, if the photoresist layer 220 is positive, a two-dimensional lattice structure, is formed by means of strip-type openings as shown in FIG. 8. On the while, if the photoresist layer 220 is negative, a two-dimensional lattice structure is formed by means of square-type openings as shown in FIG. 9. Meanwhile, the photoresist layer 220 may also be exposed to light only once. In this case, strip-type openings are repeatedly formed in one dimension in the photoresist layer 220, as shown in FIG. 10.

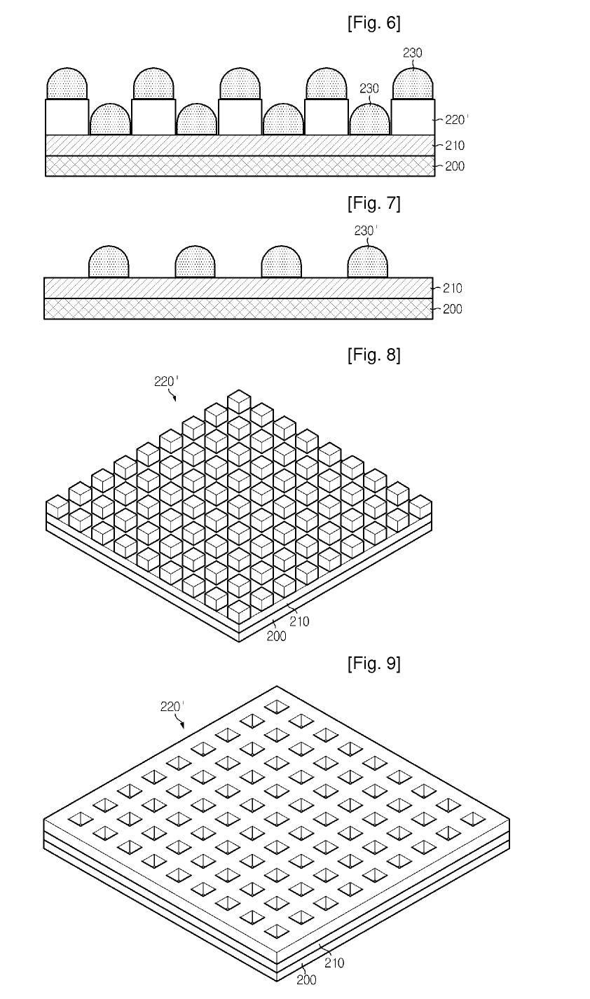

Successively, an electrochromic layer 230 is deposited on a front surface of the substrate on which the photoresist pattern 220′ is formed, as shown in FIG. 6. The electrochromic layer 230 is deposited using vacuum deposition such as sputtering, E-beam, evaporation, and laser ablation. The electrochromic layer 230 may be made of cathodic electrochromic materials such as WO₃, MoO₃, Nb₂O₅ and TiO₂, and anodic electrochromic materials such as NiO, Ir₂O₃, Rh₂O₃, CO₃O₄, Fe₂O₃, Cr₂O₃ and V₂O₅.

For example, in case the electrochromic layer 230 is made of tungsten oxide (WO₃) or titanium oxide (TiO₂), reactive sputtering is employed. In this case, tungsten or titanium is used as a metal target, and argon gas is blown into a sputter chamber together with oxygen gas.

If the electrochromic layer 230 is completely deposited, the photoresist pattern 220′ is lift off as shown in FIG. 7. Then, the electrochromic layer 230 deposited on the photoresist pattern 220′ is removed together with the photoresist pattern 220′. Thus, the electrochromic layer pattern 230′ is completely formed on the transparent electrode layer 210.

Meanwhile, the electrochromic layer pattern 230′ is formed in a region where the photoresist layer 210 is removed during the development of the photoresist layer 210. Thus, the shape of the electrochromic layer pattern 230′ varies depending on the type of the photoresist.

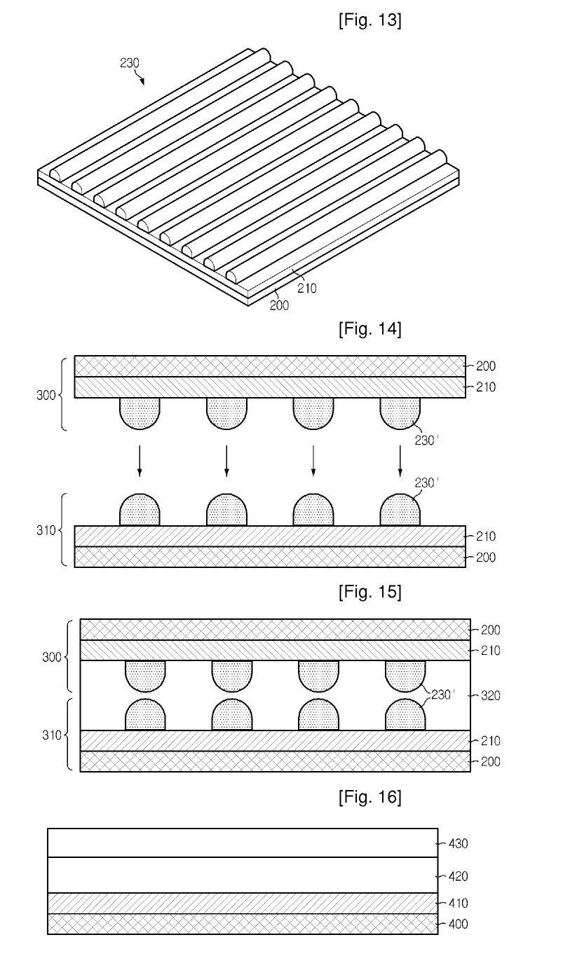

That is to say, if the photoresist is a positive type, the electrochromic layer pattern 230′ is formed in a two-dimensional lattice structure in which strip-type patterns are crossed as shown in FIG. 11. On the while, if the photoresist is a negative type, the electrochromic layer pattern 230′ is formed in a two-dimensional lattice structure in which square-type patterns separated from each other are repeated as shown in FIG. 12. Meanwhile, in case the exposure to the photoresist layer is conducted only once, the electrochromic layer pattern 230′ is formed such that strip-type patterns formed in one dimension are repeated regardless of the type of photoresist, as shown in FIG. 13.

If the electrochromic layer pattern 230′ is formed as mentioned above, a contact surface area between the electrochromic layer and the ion conductive layer may be increased, thereby capable of improving a response speed of the device. In addition, though the electrochromic layer is configured using an inorganic thin film, the inorganic thin film is not easily broken rather than the conventional case in which the electrochromic layer is formed in a sheet shape, so the present invention allows making a flexible ECD using a plastic substrate.

A substrate module in which the transparent electrode layer 210 and the electrochromic layer pattern 230′ are formed on the transparent substrate 200 according to the above embodiment may be used for manufacturing an ECD.

FIGS. 14 and 15 are schematic diagrams subsequently illustrating processes of a method for manufacturing an ECD using the substrate module prepared according to the embodiment of the present invention.

As shown in FIG. 14, first, an upper substrate module 300 and a lower substrate module 310 are prepared. Each substrate module 300, 310 is configured such that a transparent substrate 200, a transparent electrode layer 210 and an electrochromic layer pattern 230′ are laminated, and it may be prepared according to the method explained with reference to FIGS. 4 to 7.

Subsequently, while the substrate modules 300, 310 are arranged to face each other, the upper and lower substrate modules 300, 310 are fixed in a spaced-apart relationship using a spacer (not shown).

And then, as shown in FIG. 15, the upper and lower substrate modules 300, 310 are sealed using UV curing agent, thermosetting curing agent and so on, except for an injection hole for an ion conductive layer. Then, an ion conductive layer 320 is injected between the upper and lower substrate modules 300, 310, and the injection hole is sealed. Then, an ECD is completely manufactured. Preferably, the ion conductive layer 320 is a solution obtained by dissolving LiClO₄ in propylene carbonate or dissolving CF₃SO₃Li in propylene carbonate. However, the present invention is not limited thereto.

Meanwhile, the electrochromic layer patterns of the upper and lower substrate modules 300, 310 preferably have polarities different from each other. That is to say, if one electrochromic layer pattern is composed of cathodic electrochromic material, the other electrochromic layer pattern is composed of anodic electrochromic material. Then, one electrochromic layer pattern functions as an ion storage layer, and the other electrochromic layer pattern functions as an electrochromic layer for coloring or decoloring. Though not shown in the figures, it would be apparent to those having ordinary skill in the art that an electrochromic layer pattern of any one substrate module may be not used on occasions.

FIGS. 16 to 18 are schematic diagrams subsequently illustrating processes of a method for forming an electrochromic layer pattern according to a second embodiment of the present invention.

First, as shown in FIG. 16, a transparent electrode layer 410, an insulation layer 420 and a photoresist layer 430 are subsequently formed on a transparent substrate 400. Here, the substrate 400, the transparent electrode layer 410 and the photoresist layer 430 are made of the same material films as in the first embodiment, and the insulation layer 420 is made of silicon oxide film (SiO₂) or silicon nitride film (Si₃N₄). As an alternative, the insulation layer 420 may also be made of plastic resin. The insulation layer 420 is a material film for forming a spacer pattern that protects the transparent electrode layer 410 and prevents an electric short circuit between the upper and lower substrate modules while manufacturing an ECD.

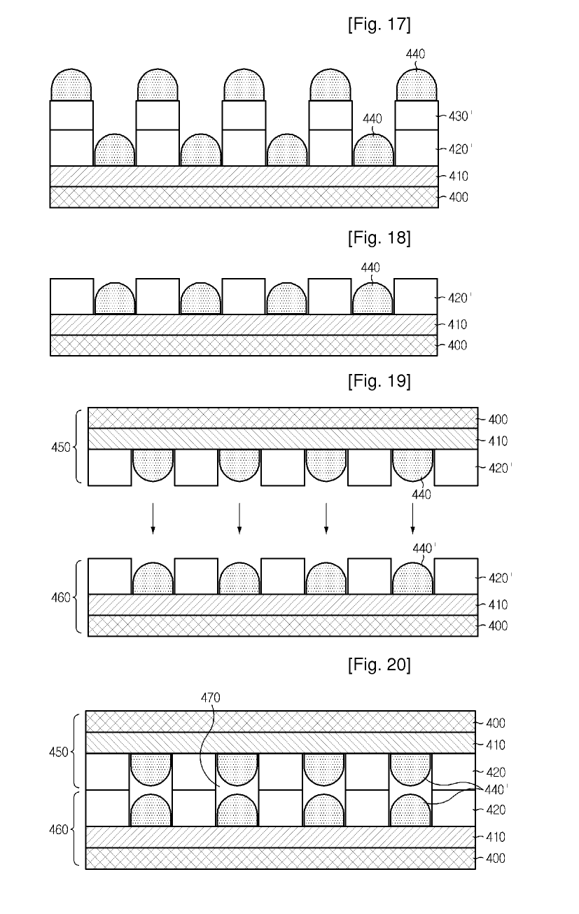

Subsequently, as shown in FIG. 17, a photoresist pattern 430′ is formed using laser interference lithography to expose the insulation layer 420. At this time, the photoresist pattern 430′ has a shape selected from ones shown in FIGS. 8 to 10.

And then, the insulation layer 420 exposed by the photoresist pattern 430′ is removed using reactive ion etching to form an insulation layer pattern 420′. After that, an electrochromic layer 440 is formed on a front surface of the transparent substrate 400. The electrochromic layer 440 is formed in openings defined by the insulation layer pattern 420′ and an upper portion of the photoresist pattern 430′.

Subsequently, as shown in FIG. 18, the photoresist pattern 430′ is lift up to remove the photoresist pattern 430′ and the electrochromic layer 440 formed thereon. Then, there remain only the insulation layer pattern 420′ and the electrochromic layer pattern 440′ formed among it, so the electrochromic layer pattern 440′ is completely formed on the transparent electrode layer 410.

If the electrochromic layer pattern 440′ is formed as mentioned above, it is possible to increase a contact surface area between the electrochromic layer and the ion conductive layer, thereby capable of improving a response speed of the device. In addition, though the electrochromic layer is composed using an inorganic thin film, the inorganic thin film is not easily broken rather than the conventional case in which the electrochromic layer is formed in a sheet shape, so the present invention allows making a flexible ECD using a plastic substrate.

A substrate module in which the transparent electrode layer 410, the insulation layer pattern 420′ and the electrochromic layer pattern 440′ are formed on the transparent substrate 400 according to the second embodiment of the present invention may be used for manufacturing an ECD.

FIGS. 19 and 20 are schematic diagrams subsequently illustrating processes of a method for manufacturing an ECD using the substrate module prepared according to the second embodiment of the present invention.

As shown in FIG. 19, first, upper and lower substrate modules 450, 460 are prepared. Each substrate module 450, 460 is configured such that a transparent substrate 400, a transparent electrode layer 410, an insulation layer pattern 420′ and an electrochromic layer pattern 440′ are laminated, and it may be prepared according to the method explained with reference to FIGS. 16 to 18.

Subsequently, as shown in FIG. 20, while the substrate modules 450, 460 are arranged such that their insulation layer patterns 420′ face each other, the upper and lower substrate modules 450, 460 are sealed using UV curing agent, thermosetting curing agent and so on, except for an injection hole for an ion conductive layer 470. And then, an ion conductive layer 470 is injected between the upper and lower substrate modules 450, 460, and the injection hole is sealed. Then, an ECD is completely manufactured. Preferably, the ion conductive layer 470 is a solution obtained by dissolving LiClO₄ in propylene carbonate or dissolving CF₃SO₃Li in propylene carbonate. However, the present invention is not limited thereto.

Meanwhile, the electrochromic layer patterns of the upper and lower substrate modules 450, 460 preferably have polarities different from each other. That is to say, if one electrochromic layer pattern is composed of cathodic electrochromic material, the other electrochromic layer pattern is composed of anodic electrochromic material. Then, one electrochromic layer pattern functions as an ion storage layer, and the other electrochromic layer pattern functions as an electrochromic layer for coloring or decoloring. Though not shown in the figures, it would be apparent to those having ordinary skill in the art that an electrochromic layer pattern of any one substrate module may be not used on occasions.

The present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

### INDUSTRIAL APPLICABILITY

In one aspect of the present invention, a contact surface area between the electrochromic layer pattern and the ion conductive layer is greater, so an ECD of the present invention has a faster response speed rather than a conventional one. Also, though the electrochromic layer is composed of an inorganic thin film weak against mechanical strength and also a flexible plastic substrate is employed, the present invention may prevent breakdown of the electrochromic layer, thereby improving durability of the ECD.

In another aspect of the present invention, the electrochromic layer is patterned using laser interference lithography that needs no masking process, so the present invention may improve productivity and allow a thinner design of the ECD rather than a conventional technique that patterns nano-sized holes in an electrochromic layer using general photolithography or preparing the electrochromic layer using a porous thin film.

1. An electrochromic device (ECD), comprising:
first and second transparent substrates arranged to face each other;
first and second sheet-type transparent electrodes respectively formed on the first and second transparent substrates to face each other;
an electrochromic layer pattern formed on at least one of the first and second transparent electrodes through openings of a photoresist pattern formed by laser interference lithography; and
an ion conductive layer for sealingly filling a space defined by the electrochromic layer pattern and surfaces of the first and second transparent electrodes.

2. The ECD according to claim 1,
wherein the electrochromic layer pattern is formed in a way of depositing an electrochromic layer using the photoresist pattern formed by laser interference lithography as a mask, and then lifting up the photoresist pattern.

3. The ECD according to claim 1,
wherein the electrochromic layer pattern has a lattice structure in which strip-type patterns are repeated in two dimensions.

4. The ECD according to claim 1,
wherein the electrochromic layer pattern has a lattice structure in which square-type patterns are repeated in two dimensions.

5. The ECD according to claim 1,
wherein the electrochromic layer pattern has a structure in which strip-type patterns are repeated in one dimension.

6. An ECD, comprising:
first and second transparent substrates arranged to face each other;
first and second sheet-type transparent electrodes respectively formed on the first and second transparent substrates to face each other;
an insulation layer pattern formed on at least one of the first and second transparent electrodes and having openings regularly repeated;
an electrochromic layer pattern formed in the openings of the insulation layer pattern; and
an ion conductive layer for sealingly filling a space defined by a surface of the insulation layer pattern, a surface of the electrochromic layer pattern, and surfaces of the first and second transparent electrodes.

7. The ECD according to claim 6,
wherein the insulation layer pattern is formed in a way of etching an insulation layer formed on the first and/or second transparent electrodes using a photoresist pattern formed by laser interference lithography as a mask.

8. The ECD according to claim 6,
wherein, after the insulation layer pattern is formed by etching an insulation layer formed on the first and/or second transparent electrodes using a photoresist pattern formed by laser interference lithography as an etching mask, the electrochromic layer pattern is formed in a way of depositing an electrochromic layer on a front surface of the substrates and then lifting up the photoresist pattern.

9. The ECD according to claim 6,
wherein the insulation layer pattern is formed on both of the first and second transparent electrodes, and
wherein the insulation layer pattern formed on the first transparent electrode faces the insulation layer pattern formed on the second transparent electrode in contact with each other.

10. The ECD according to claim 6,
wherein the insulation layer pattern has a lattice structure in which strip-type patterns are repeated in two dimensions, and
wherein the electrochromic layer pattern is formed in the openings defined by the insulation layer pattern and has a lattice structure in which square-type patterns are repeated in two dimensions.

11. The ECD according to claim 6,
wherein the insulation layer pattern has a lattice structure in which square-type patterns are repeated in two dimensions, and
wherein the electrochromic layer pattern is formed in the openings defined by the insulation layer pattern and has a lattice structure in which strip-type patterns are repeated in two dimensions.

12. The ECD according to claim 6,
wherein the insulation layer pattern has a structure in which strip-type patterns are repeated in one dimension, and
wherein the electrochromic layer pattern is formed in the openings defined by the insulation layer pattern and has a structure in which strip-type patterns are repeated in one dimension.

13. A method for forming an electrochromic layer pattern, comprising:
(a) forming a sheet-type transparent electrode layer on a transparent substrate;
(b) forming a photoresist layer on the transparent electrode layer;
(c) patterning the photoresist layer by means of laser interference lithography to form a photoresist pattern having openings that expose the transparent electrode layer at regular intervals; and
(d) forming an electrochromic layer pattern in the openings by depositing an electrochromic layer on a front surface of the transparent substrate and lifting up the photoresist pattern.

14. The method for forming an electrochromic layer pattern according to claim 13,
wherein the photoresist layer has a positive type,
wherein laser beam exposure is conducted two times in the laser interference lithography of the step (c) such that second laser beam exposure is conducted with the substrate being rotated as much as 90 degrees after first laser beam exposure, and
wherein the openings defined by the photoresist pattern have a structure in which strip-type openings are repeated in two dimensions.

15. The method for forming an electrochromic layer pattern according to claim 13,
wherein the photoresist layer has a negative type,
wherein laser beam exposure is conducted two times in the laser interference lithography of the step (c) such that second laser beam exposure is conducted with the substrate being rotated as much as 90 degrees after first laser beam exposure, and
wherein the openings defined by the photoresist pattern have a structure in which square-type openings are repeated in two dimensions.

16. The method for forming an electrochromic layer pattern according to claim 13,
wherein laser beam exposure is conducted once in the laser interference lithography of the step (c), and
wherein the openings defined by the photoresist pattern have a structure in which strip-type openings are repeated in one dimension.

17. A method for manufacturing an ECD, comprising:
(a) forming a sheet-type transparent electrode layer on a transparent substrate;
(b) forming a photoresist layer on the transparent electrode layer;
(c) patterning the photoresist layer by means of laser interference lithography to form a photoresist pattern having openings that expose the transparent electrode layer at regular intervals;
(d) forming an electrochromic layer pattern in the openings by depositing an electrochromic layer on a front surface of the transparent substrate and lifting up the photoresist pattern;
(e) forming a transparent electrode layer on the transparent substrate to form an upper substrate module;
(f) arranging the upper substrate module and a lower substrate modules to face each other, and fixing the upper and lower substrate modules in a spaced-apart relationship using a spacer; and
(g) sealing the fixed upper and lower substrate modules, injecting an ion conductive layer therein, and then sealing the upper and lower substrate modules containing the ion conductive layer.

18. A method for manufacturing an ECD, comprising:
(a) forming a sheet-type transparent electrode layer on a transparent substrate;
(b) forming a photoresist layer on the transparent electrode layer;
(c) patterning the photoresist layer by means of laser interference lithography to form a photoresist pattern having openings that expose the transparent electrode layer at regular intervals;
(d) forming an electrochromic layer pattern in the openings by depositing an electrochromic layer on a front surface of the transparent substrate and lifting up the photoresist pattern;
the steps (a) to (d) being executed two times to form an upper substrate module and a lower substrate module,
(e) arranging the upper and lower substrate modules to face each other, and fixing the upper and lower substrate modules in a spaced-apart relationship using a spacer; and
(f) sealing the fixed upper and lower substrate modules, injecting an ion conductive layer therein, and sealing the upper and lower substrate modules containing the ion conductive layer.

19. The method for manufacturing an ECD according to claim 18,
wherein the electrochromic layer patterns of the upper and lower substrate modules have polarities different from each other.

20. A method for manufacturing an ECD, comprising:
(a) forming a sheet-type transparent electrode layer on a transparent substrate;
(b) forming an insulation layer on the transparent electrode layer;
(c) forming a photoresist layer on the insulation layer;
(d) patterning the photoresist layer by means of laser interference lithography to form a photoresist pattern having openings that expose the insulation layer at regular intervals;
(e) etching the insulation layer using the photoresist pattern as an etching mask to form an insulation layer pattern having openings that expose the transparent electrode layer at regular intervals; and
(f) forming an electrochromic layer pattern in the openings defined by the insulation layer pattern by depositing an electrochromic layer on a front surface of the transparent substrate and lifting up the photoresist pattern.

21. The method for manufacturing an ECD according to claim 20,
wherein the photoresist layer has a positive type,
wherein laser beam exposure is conducted two times in the laser interference lithography of the step (d) such that second laser beam exposure is conducted with the substrate being rotated as much as 90 degrees after first laser beam exposure, and
wherein the openings defined by the photoresist pattern and the insulation layer pattern have a structure in which strip-type openings are repeated in two dimensions.

22. The method for manufacturing an ECD according to claim 20,
wherein the photoresist layer has a negative type,
wherein laser beam exposure is conducted two times in the laser interference lithography of the step (d) such that second laser beam exposure is conducted with the substrate being rotated as much as 90 degrees after first laser beam exposure, and
wherein the openings defined by the photoresist pattern and the insulation layer pattern have a structure in which square-type openings are repeated in two dimensions.

23. The method for manufacturing an ECD according to claim 20,
wherein laser beam exposure is conducted one time in the laser interference lithography of the step (d), and
wherein the openings defined by the photoresist pattern and the insulation layer pattern have a structure in which strip-type openings are repeated in one dimension.

24. A method for manufacturing an ECD, comprising:
(a) forming a sheet-type transparent electrode layer on a transparent substrate;
(b) forming an insulation layer on the transparent electrode layer;
(c) forming a photoresist layer on the insulation layer;
(d) patterning the photoresist layer by means of laser interference lithography to form a photoresist pattern having openings that expose the insulation layer at regular intervals;
(e) etching the insulation layer using the photoresist pattern as an etching mask to form an insulation layer pattern having openings that expose the transparent electrode layer at regular intervals;
(f) forming an electrochromic layer pattern in the openings defined by the insulation layer pattern by depositing an electrochromic layer on a front surface of the transparent substrate and lifting up the photoresist pattern, thereby forming a lower substrate module;
(g) forming a transparent electrode layer on a transparent substrate to form an upper substrate module;
(h) arranging the upper and lower substrate modules to face each other, and adhering an upper surface of the insulation layer pattern of the lower substrate module to the transparent electrode layer of the upper substrate module; and
(i) sealing the upper and lower substrate modules, injecting an ion conductive layer therein, and sealing the upper and lower substrate modules containing the ion conductive layer.

25. The method for manufacturing an ECD according to claim 24,
wherein the step (g) further includes forming an insulation layer pattern, which is identical to the insulation layer pattern formed on the lower substrate module, on the transparent electrode layer of the upper substrate module, and
wherein the step (h) further includes adhering the insulation layer patterns of the lower and upper substrate modules with each other to face each other.

26. A method for manufacturing an ECD, comprising:
(a) forming a sheet-type transparent electrode layer on a transparent substrate;
(b) forming an insulation layer on the transparent electrode layer;
(c) forming a photoresist layer on the insulation layer;
(d) patterning the photoresist layer by means of laser interference lithography to form a photoresist pattern having openings that expose the insulation layer at regular intervals;
(e) etching the insulation layer using the photoresist pattern as an etching mask to form an insulation layer pattern having openings that expose the transparent electrode layer at regular intervals;
(f) forming an electrochromic layer pattern in the openings defined by the insulation layer pattern by depositing an electrochromic layer on a front surface of the transparent substrate and lifting up the photoresist pattern;
the steps (a) to (f) being executed two times to form an upper substrate module and a lower substrate module,
(g) arranging the upper and lower substrate modules to face each other, and adhering an upper surface of the insulation layer pattern of the lower substrate module to an upper surface of the insulation layer pattern of the upper substrate module; and
(h) sealing the upper and lower substrate modules, injecting an ion conductive layer therein, and sealing the upper and lower substrate modules containing the ion conductive layer.

27. The method for manufacturing an ECD according to claim 26,
wherein the electrochromic layer patterns of the upper and lower substrate modules have polarities different from each other.
